(19) United States
(12) Patent Application Publication
(10) Pub. No.: US 2023/0171970 A1
(43) Pub. Date: Jun. 1, 2023

(54) SEMICONDUCTOR STRUCTURE AND FABRICATION METHOD THEREOF

(71) Applicants: CHANGXIN MEMORY TECHNOLOGIES, INC., Hefei (CN); Beijing Superstring Academy of Memory Technology, Beijing (CN)

(72) Inventors: Xiaoguang WANG, Hefei (CN); Huihui LI, Hefei (CN); Wei CHANG, Hefei (CN); Kanyu CAO, Hefei (CN)

(21) Appl. No.: 17/827,808

(22) Filed: May 30, 2022

Related U.S. Application Data
(63) Continuation of application No. PCT/CN2022/078086, filed on Feb. 25, 2022.

(30) Foreign Application Priority Data
Nov. 30, 2021 (CN) 202111447226.2

(51) Int. Cl. H01L 27/105

(52) U.S. Cl. CPC H01L 27/1052

(57) ABSTRACT

Embodiment provides a semiconductor structure and a fabrication method thereof, and relates to the field of semiconductor technology. The method includes: providing a substrate having an array region including a first region and a second region arranged adjacently; and forming a first memory in the first region and forming a second memory in the second region by means of a same fabrication process, the fabrication process being a process configured for fabricating the first memory.

### CROSS-REFERENCE TO RELATED APPLICATION

The present disclosure is a continuation of PCT/CN2022/078086, filed on Feb. 25, 2022, which claims priority to Chinese Patent Application No. 202111447226.2 titled “SEMICONDUCTOR STRUCTURE AND FABRICATION METHOD THEREOF” and filed to the State Intellectual Property Office on Nov. 30, 2021, the entire contents of which are incorporated herein by reference.

### TECHNICAL FIELD

The present disclosure relates to the field of semiconductor technology, and more particularly, to a semiconductor device and a fabrication method thereof.

### BACKGROUND

Magnetic Random Access Memory (MRAM for short) is a non-volatile memory based on integration of silicon-based complementary oxide semiconductor and magnetic tunnel junction (MTJ) technologies. As a memory based on transistor structures and capacitor structures, Dynamic Random Access Memory (DRAM) has higher storage density and high-speed read capability.

However, there is no effective way to integrate memory cells of the MRAM with memory cells of the DRAM in the related technologies.

### SUMMARY

A first aspect of embodiments of the present disclosure provides a method for fabricating a semiconductor structure, and the method includes following steps:
providing a substrate having an array region including a first region and a second region arranged adjacently; and
forming a first memory in the first region and forming a second memory in the second region by means of a same fabrication process, which is a process configured for fabricating the first memory.

A second aspect of the embodiments of the present disclosure provides a semiconductor structure, which is fabricated by the method for fabricating a semiconductor structure described in the above embodiments. The semiconductor structure includes:
a substrate having an array region, where the array region includes a first region and a second region arranged adjacently;
a first memory arranged in the first region; and
a second memory arranged in the second region.

In some embodiments, the first memory includes a dynamic random access memory (DRAM), and the second memory includes a magnetic random access memory (MRAM).

The first memory also includes a bit line contact structure, and the second memory also includes a source line contact structure, where the bit line contact structure and the source line contact structure are positioned in a same layer and are fabricated by means of a same process step.

In addition to the technical problems solved by the embodiments of the present disclosure described above, technical features constituting technical solutions and beneficial effects brought by the technical features of these technical solutions, other technical problems that can be solved by the semiconductor structure and the fabrication method thereof provided by the embodiments of the present disclosure, other technical features included in the technical solutions and beneficial effects brought by these technical features will be described in further detail in some implementations.

### BRIEF DESCRIPTION OF THE DRAWINGS

To describe the technical solutions of the embodiments of the present disclosure or those of the prior art more clearly, the accompanying drawings required for describing the embodiments or the prior art will be briefly introduced below. Apparently, the accompanying drawings in the following description are merely some embodiments of the present disclosure. To those of ordinary skills in the art, other accompanying drawings may also be derived from these accompanying drawings without creative efforts.

FIG. 1 is a process flow diagram of a method for fabricating a semiconductor structure according to an embodiment of the present disclosure;

FIG. 2 is a vertical view of a substrate in the method for fabricating a semiconductor structure according to an embodiment of the present disclosure;

FIG. 3 is a schematic structural diagram of an active area and an isolation structure formed in the method for fabricating a semiconductor structure according to an embodiment of the present disclosure;

FIG. 4 is a schematic structural diagram of gate trenches formed in the method for fabricating a semiconductor structure according to an embodiment of the present disclosure;

FIG. 5 is a schematic structural diagram of gate structures formed in the method for fabricating a semiconductor structure according to an embodiment of the present disclosure;

FIG. 6 is a schematic structural diagram of grooves formed in the method for fabricating a semiconductor structure according to an embodiment of the present disclosure;

FIG. 7 is a schematic structural diagram of a bit line contact structure and a source line contact structure formed in the method for fabricating a semiconductor structure according to an embodiment of the present disclosure;

FIG. 8 is a schematic structural diagram of a first bit line structure and a source line structure formed in the method for fabricating a semiconductor structure according to an embodiment of the present disclosure;

FIG. 9 is a schematic structural diagram of a first dielectric layer formed in the method for fabricating a semiconductor structure according to an embodiment of the present disclosure;

FIG. 10 is a schematic structural diagram of vias formed in the method for fabricating a semiconductor structure according to an embodiment of the present disclosure;

FIG. 11 is a schematic structural diagram of a capacitive contact structure and a source line contact structure formed in the method for fabricating a semiconductor structure according to an embodiment of the present disclosure;

FIG. 12 is a schematic structural diagram of a first conductive layer formed in the method for fabricating a semiconductor structure according to an embodiment of the present disclosure;

FIG. 13 is a schematic structural diagram of bottom electrode contacts formed in the method for fabricating a semiconductor structure according to an embodiment of the present disclosure;

FIG. 14 is a schematic structural diagram of a first insulating layer formed in the method for fabricating a semiconductor structure according to an embodiment of the present disclosure;

FIG. 15 is a schematic structural diagram of a magnetic layer formed in the method for fabricating a semiconductor structure according to an embodiment of the present disclosure;

FIG. 16 is a schematic structural diagram of a magnetic tunnel junction formed in the method for fabricating a semiconductor structure according to an embodiment of the present disclosure;

FIG. 17 is a schematic structural diagram of a second insulating layer formed in the method for fabricating a semiconductor structure according to an embodiment of the present disclosure;

FIG. 18 is a schematic structural diagram of a capacitor and a connection pad formed in the method for fabricating a semiconductor structure according to an embodiment of the present disclosure;

FIG. 19 is a schematic structural diagram of first conductive pillars and second conductive pillars formed in the method for fabricating a semiconductor structure according to an embodiment of the present disclosure; and

FIG. 20 is a schematic structural diagram of an interconnect layer and a second bit line structure formed in the method for fabricating a semiconductor structure according to an embodiment of the present disclosure.

### DETAILED DESCRIPTION

At present, a memory generally includes a dynamic random access memory (DRAM) and a magnetic random access memory (MRAM), both of which have their own advantages. In the process fabrication, DRAM and MRAM are generally fabricated by their own fabrication processes, and the same memory cannot have two different memory cells, which limits the development of the memory.

In view of the above technical problems, in the embodiments of the present disclosure, a first memory and a second memory are simultaneously formed on a substrate by means of the same fabrication process, such that the same semiconductor structure has two different types of memories. In this way, fabrication steps of the semiconductor structure can be simplified, and performance of the semiconductor structure can also be improved.

To make the above objectives, features, and advantages of the embodiments of the present disclosure more apparent and lucid, the technical solutions in the embodiments of the present disclosure will be described clearly and completely below with reference to the accompanying drawings in the embodiments of the present disclosure. Apparently, the described embodiments are merely some but not all of the embodiments of the present disclosure. All other embodiments obtained by persons of ordinary skill in the art based on the embodiments of the present disclosure without creative efforts shall fall within the protection scope of the present disclosure.

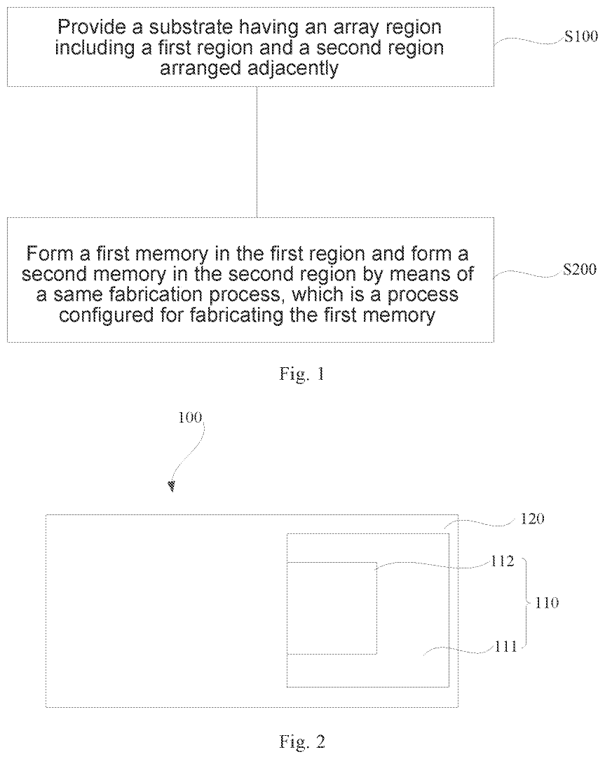

FIG. 1 is a flow diagram of a method for fabricating a semiconductor structure according to an embodiment of the present disclosure, and FIGS. 2 to 20 are schematic diagrams of various stages of the method for fabricating a semiconductor structure. The semiconductor structure and the fabrication method thereof are described in detail below with reference to FIGS. 2 to 20.

As shown in FIG. 1, the method for fabricating a semiconductor structure provided by an embodiment of the present disclosure includes following steps.

Step S100: providing a substrate having an array region, which includes a first region and a second region arranged adjacently.

As shown in FIG. 2, the substrate 100 has an array region 110 and a peripheral circuit region 120 arranged around the array region 110, where the array region 110 is configured to arrange a memory array, and the peripheral circuit region 120 is configured to arrange a logic circuit to control the memory array, to implement read/write function of the memory array.

The array region 110 has a first region 111 and a second region 112 arranged adjacently, which may be understood that the first region 111 and the second region 112 are arranged side by side in a certain direction, or may also be understood that the first region 111 is arranged around the second region 112 (as shown in FIG. 2), or the second region 112 is arranged around the first region 111.

Step S200: forming a first memory in the first region and forming a second memory in the second region by means of a same fabrication process, which is a process configured for fabricating the first memory.

In this embodiment, a first memory 200 and a second memory 300 are respectively formed in the first region and the second region by means of the process configured for fabricating the first memory, such that the same semiconductor structure has two different types of memories. In this way, fabrication steps of the semiconductor structure can be simplified, and performance of the semiconductor structure can also be improved.

In some embodiments, the first memory 200 is a dynamic random access memory (DRAM), the second memory 300 is a magnetic random access memory (MRAM), and the fabrication process is a process configured for fabricating a DRAM.

A memory array having a higher integration can be fabricated by means of the process configured for fabricating a DRAM. Therefore, in this embodiment, the DRAM is formed in the first region by means of the process configured for fabricating a DRAM, and the MRAM is formed in the second region. In this way, in one aspect, the same semiconductor structure may have the DRAM and the MRAM at the same time, which simplifies the fabrication steps of the semiconductor structure, and also satisfies usage requirements of different users, and improves applicability of the semiconductor structure. In another aspect, compared with a technical solution where the MRAM is fabricated by means of a process configured for fabricating an MRAM, the integration of the memory array in the MRAM can be improved, and it is convenient for the development of the semiconductor structure to the direction of integration.

In addition, the first memory is prone to defects after being used for a period of time. In this embodiment, the second memory is formed in the second region, such that when the first memory is defective, the second memory may be employed to replace the defective first memory. In this way, management of defective memory cells throughout the life cycle of DRAM products can be achieved. Furthermore, test fees/time and areas scan be saved for the defective memory cells.

In some embodiments, the providing a substrate having an array region includes following steps.

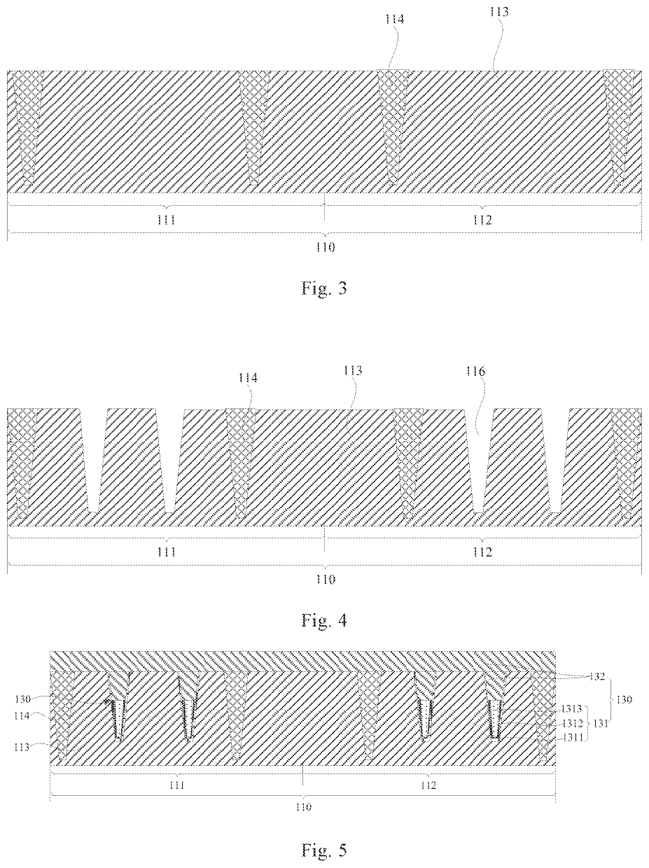

As shown in FIG. 3, a plurality of active areas 113 spaced apart and isolation structures 114 configured to separate the plurality of active areas 113 are formed in the substrate 100. Exemplarily, the substrate 100 is first patterned to form isolation trenches in the substrate 100, and then an insulating material is deposited in the isolation trenches by means of a deposition process to form the isolation structures 114, but not limited thereto.

The substrate 100 may be made from a semiconductor material, which may be one or more of silicon, germanium, silicon-germanium compound and silicon-carbon compound. A material of the isolation structure 114 is an insulating material, which includes any one of silicon oxide, silicon nitride, silicon oxynitride and silicon carbonitride or any combination thereof

In this embodiment, mutual isolation between the plurality of active areas 113 is achieved by means of the isolation structures 114, to avoid electrical connection between semiconductor devices in adjacent active areas 113 and improve the performance of the semiconductor structure.

After the plurality of active areas 113 are formed, buried-gate transistors 130 are formed in each of the plurality of active areas 113, where the buried-gate transistors 130 positioned in the first region 111 serve as read/write transistors of the first memory 200, and the buried-gate transistors 130 positioned in the second region 112 serve as read/write transistors of the second memory 300, and structures of the buried-gate transistors 130 are as shown in FIG. 5.

Number of the buried-gate transistors 130 in each of the plurality of active areas 113 is two, and gate structures of the two buried-gate transistors 130 share the same source or the same drain. In this way, the integration of the read/write transistors per unit area can be improved, such that the integration of memory cells per unit area can be improved, and thus the performance of the semiconductor structure can be improved.

In addition, processes for forming the buried-gate transistor 130 may be as follows.

As shown in FIG. 4, a gate trench 116 and a source and a drain respectively positioned on two sides of the gate trench 116 are formed in each of the plurality of active areas 113. When each of the plurality of active areas 113 has two buried-gate transistor 130, correspondingly, each of the plurality of active areas 113 is internally provided with two gate trenches 116 spaced apart, where the substrate positioned between the two gate trenches 116 may form the source, and a side facing away from the two gate trenches 116 is the drain.

As shown in FIG. 5, a gate structure 131 is formed in each of the gate trenches 116, where each of the gate structure 131 includes an oxide layer 1311 and a barrier layer 1312 stacked on an inner wall of the gate trench 116, and a gate 1313 arranged in a region enclosed by the barrier layer 1312, where the gate 1313 is flush with a top surface of the barrier layer 1312 and is lower than a top surface of the oxide layer 1311.

A material of the oxide layer 1311 may include silicon oxide.

The barrier layer 1312 may include a conductive material such as titanium nitride. While preventing the conductive material in the gate 1313 from permeating into the substrate 100, the titanium nitride also has conductivity and thus ensures the performance of the semiconductor structure.

A material of the gate 1313 may include metal tungsten.

Next, a gate protection layer 132 may be formed by means of a deposition process, where the gate protection layer 132 covers a surface of the substrate 100 and fills up the gate trenches 116 positioned above the gate 1313.

A material of the gate protection layer 132 can include any one of silicon oxide, silicon nitride, silicon oxynitride and silicon carbonitride or any combination thereof, and the gate protection layer 132 can prevent insulation between the gate structure 131 and a semiconductor device arranged on the gate structure 131.

In this embodiment, the read transistor of the first memory and the read transistor of the second memory are synchronously formed in the substrate by means of the same fabrication process. Compared with the technical solution where the read transistor of the first memory and the read transistor of the second memory are separately fabricated by means of two different fabrication processes, fabrication steps of the semiconductor structure can be simplified, and fabrication efficiency can be improved.

In some embodiments, after the forming buried-gate transistors in each of the plurality of active areas 113, the fabrication method also includes following steps.

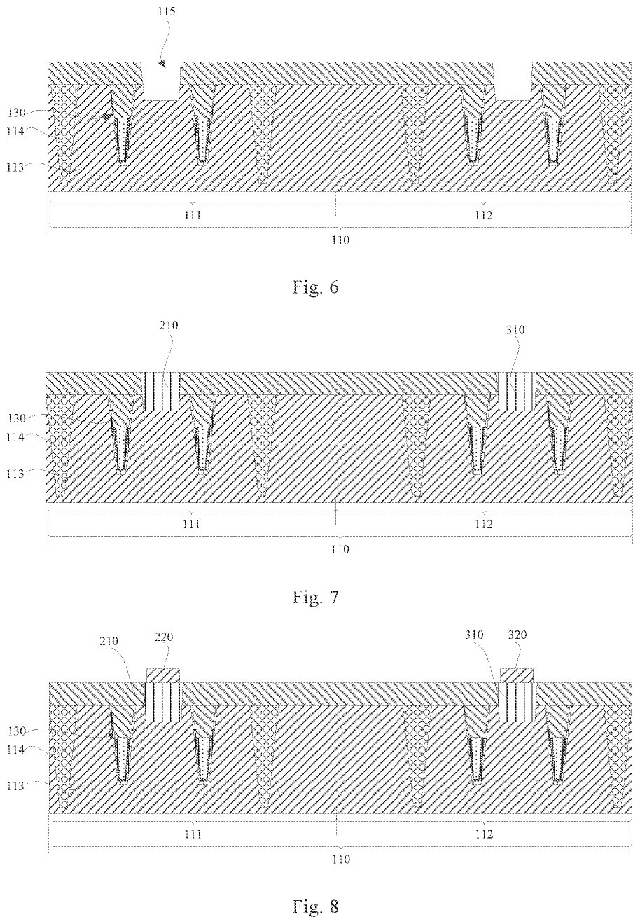

As shown in FIG. 6, a first mask layer is formed on the substrate, the first mask layer is patterned, and part of a thickness of the substrate 100 is etched and removed by using the patterned first mask layer as a mask to form a plurality of grooves 115 in the substrate 100, where each of the plurality of grooves 115 exposes part of a given one of the plurality of active areas 113. For example, if the adjacent buried-gate transistors 130 share one source, each of the plurality of grooves 115 exposes the source of the given active area 113, and the plurality of grooves 115 are arranged in a one-to-one correspondence with the sources.

As shown in FIG. 7, after the plurality of grooves 115 are formed, a conductive material is deposited into each of the plurality of grooves 115 by means of a deposition process to form a first conductive structure, where the first conductive structure positioned in the first region 111 serves as a bit line contact structure 210 of the first memory 200, and the first conductive structure positioned in the second region 112 serves as a source line contact structure 310 of the second memory 300, where the conductive material may be polysilicon.

In this embodiment, the bit line contact structure 210 and the source line contact structure 310 are respectively formed in the first region 111 and the second region 112 by means of the same etching process and the deposition process, which plays a role of simplifying the fabrication processes.

After the forming a first conductive structure in each of the plurality of grooves 115, the fabrication method also includes following steps.

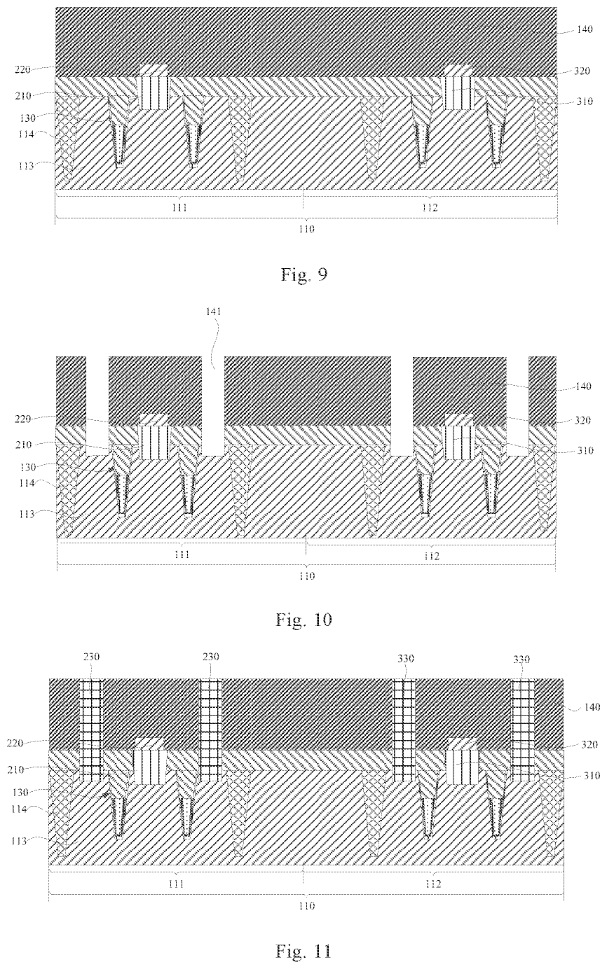

As shown in FIG. 8, a first bit line structure 220 and a source line structure 320 are formed on the substrate 100. The first bit line structure 220 is positioned in the first region 111 and is connected to the bit line contact structure 210, and the source line structure 320 is positioned in the second region 112 and is connected to the source line contact structure 310.

Exemplarily, an initial structure layer may be formed on the substrate 100, where the initial structure layer includes an initial first conductive layer, an initial second conductive layer, and an initial insulating cap layer stacked. The initial first conductive layer is arranged on the substrate 100, then a second mask layer is formed on the initial insulating cap layer, then the second mask layer is patterned, and then the initial insulating cap layer, the initial second conductive layer and the initial first conductive layer are sequentially etched by using the patterned second mask layer is as a mask to form an insulating cap layer, a second conductive layer and a first conductive layer stacked. The insulating cap layer, the second conductive layer and the first conductive layer positioned in the same vertical direction constitute a transition structure, and number of transition structures is in one-to-one correspondence with number of first conductive structures. That is, the transition structure above the first region 111 is positioned on the bit line contact structure 210, and the transition structure above the second region 112 is positioned on the source line contact structure 310.

Next, an isolation spacer is formed on a side of each of the transition structures. Exemplarily, the isolation spacer includes a silicon nitride layer, a silicon oxide layer and a silicon nitride layer which are stacked in sequence, such that the isolation spacer and the transition structure above the first region 111 constitute the first bit line structure 220, and the isolation spacer and the transition structure above the second region 112 constitute the source line structure 320.

After the forming a first bit line structure 220 and a source line structure 320 on the substrate 100, the method for fabricating a semiconductor structure also includes following steps.

As shown in FIG. 9, a first dielectric layer 140 is formed, where the first dielectric layer 140 covers the first bit line structure 220 and the source line structure 320, and the first dielectric layer 140 is configured to achieve the insulation between the first bit line structure 220 and the source line structures 320. A material of the first dielectric layer 140 includes insulating materials such as silicon oxide or silicon nitride.

Next, as shown in FIG. 10, the first dielectric layer 140 is patterned to form a plurality of vias 141 spaced apart in the first dielectric layer 140, where each of the plurality of vias 141 extends into the substrate 100 and exposes part of the given active area 113. Taking the orientation shown in FIG. 10 as an example, the two vias 141 positioned above the first region 111 respectively expose the drains of two of the plurality of active areas 113 positioned in the first region 111, and the two vias 141 positioned above the second region 112 respectively expose the drains of two of the plurality of active areas 113 positioned in the second region 112.

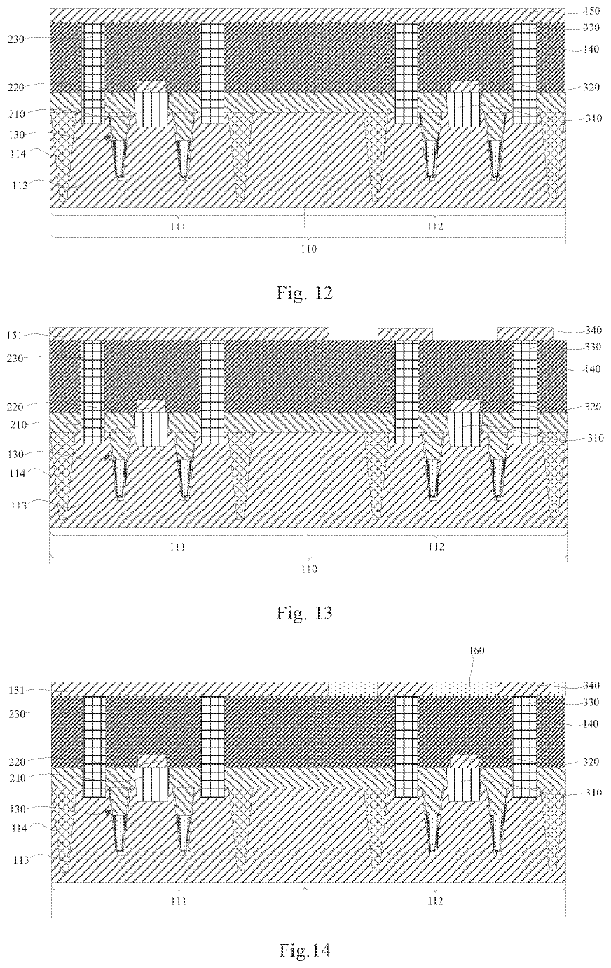

Finally, as shown in FIG. 11, a plurality of second conductive structures spaced apart are formed in the first dielectric layer 140. That is, a conductive material is deposited in each of the plurality of vias 141 to form a plurality of second conductive structures.

Some of the plurality of second conductive structures positioned in the first region 111 serve as capacitive contact structures 230 electrically connected to some of the plurality of active areas 113 positioned in the first region 111, and some the plurality of second conductive structures positioned in the second region 112 serve as conductive plugs 330 electrically connected to some of the plurality of active areas 113 positioned in the second region 112.

In this embodiment, the capacitive contact structures 230 and the conductive plugs 330 are respectively formed above the first region 111 and the second region 112 by means of the same etching process and the same deposition process, which plays a role of simplifying the fabrication processes.

In some embodiments, after the forming a plurality of second conductive structures spaced apart in the first dielectric layer 140, the method for fabricating a semiconductor structure also includes following steps.

As shown in FIG. 12, a conductive layer 150 is formed on the first dielectric layer 140 by means of a deposition process, where a material of the conductive layer 150 may include one of metal tungsten, metal aluminum, metal copper or metal titanium.

As shown in FIG. 13, the conductive layer 150 positioned in the second region 112 is patterned to form a plurality of bottom electrode contacts 340 spaced apart, where each of the plurality of bottom electrode contacts 340 is electrically connected to one of the conductive plugs 330 positioned in the second region 112.

That is, part of the conductive layer 150 above the second region 112 is removed, the conductive layer 150 retained constitutes the plurality of bottom electrode contacts 340, and the conductive layer 150 retained above the first region 111 constitutes the first conductive layer 151.

Next, as shown in FIG. 14, a first insulating layer 160 may be respectively formed between the first conductive layer 151 and one of the plurality of bottom electrode contacts 340 close to the first conductive layer 151 and between adjacent two of the plurality of bottom electrode contacts 340. The first insulating layer 160 is configured to achieve insulation therebetween, where a material of the first insulating layer 160 may include silicon oxide or silicon nitride.

After the plurality of bottom electrode contacts 340 and the first insulating layer 160 are formed, the method for fabricating a semiconductor structure also includes: forming a magnetic tunnel junction 350 on each of the plurality of bottom electrode contacts 340.

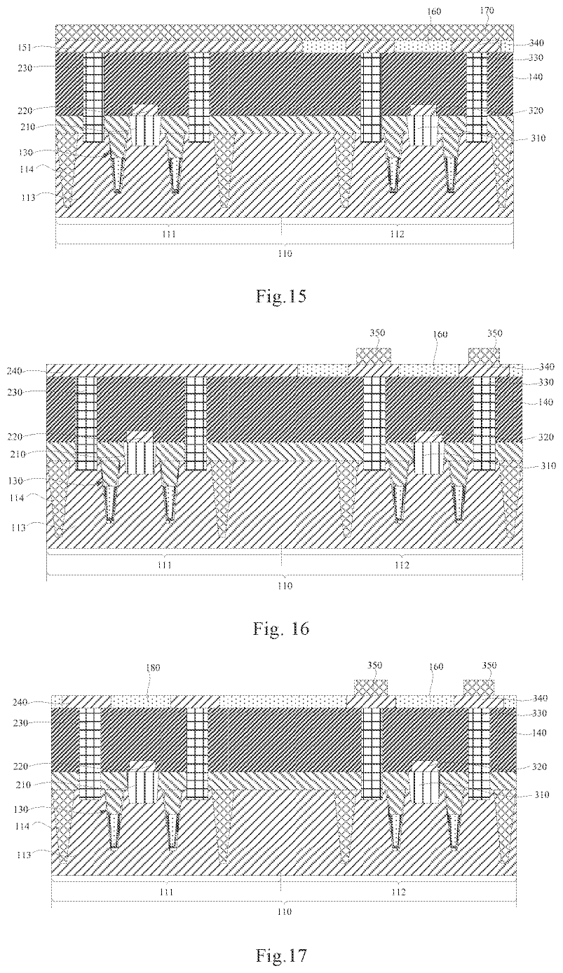

Exemplarily, as shown in FIG. 15 and FIG. 16, a magnetic layer 170 is formed on the plurality of bottom electrode contacts 340 and the first insulating layer 160, and then the magnetic layer 170 is patterned to remove part of the magnetic layer 170, such that the magnetic layer 170 on the plurality of bottom electrode contacts 340 above the second region 112 is retained, and the retained magnetic layer 170 constitutes the magnetic tunnel junction 350, where the magnetic tunnel junction 350 includes a fixed layer, a tunneling layer, and a free layer stacked. When the semiconductor structure is operating normally, a magnetization direction of the free layer may be changed, while a magnetization direction of the fixed layer remains unchanged. When the magnetization direction of the free layer changes with respect to the magnetization direction of the fixed layer, a resistance value of the magnetic memory device changes accordingly, and corresponds to different stored information.

Because memory cells of the DRAM are different from memory cells of the MRAM, the magnetic tunnel junction 350 is formed only for MRAM in this step.

In some embodiments, after the forming a magnetic tunnel junction 350 on each of the plurality of bottom electrode contacts 340, the method for fabricating a semiconductor structure also includes following steps.

The conductive layer 150 positioned in the first region 111 is patterned to form a plurality of landing pads 240 spaced apart, where the plurality of landing pads 240 are arranged in a one-to-one correspondence with the plurality of capacitive contact structures 230.

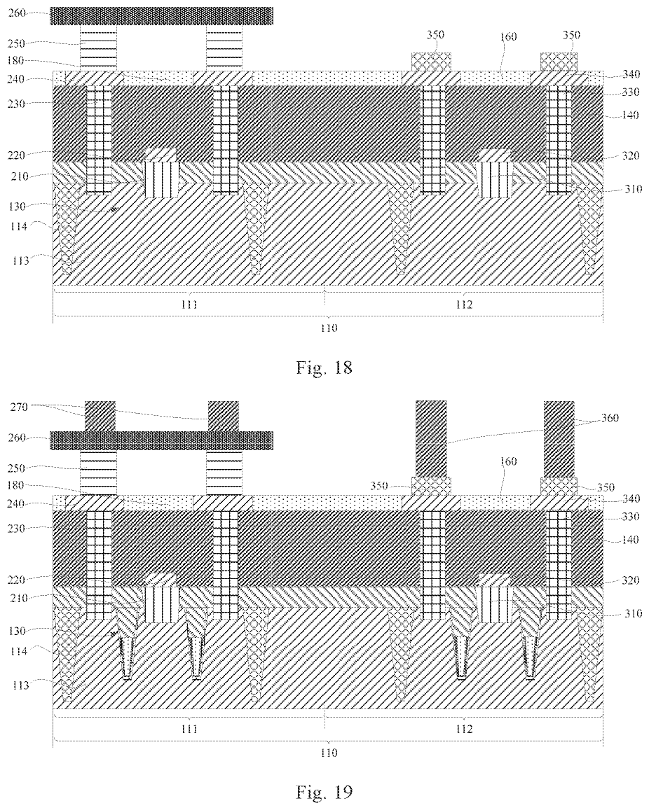

That is, as shown in FIG. 17, part of the first conductive layer 151 is removed, and the first conductive layer 151 retained constitutes a plurality of landing pads 240. To achieve the insulation between adjacent two of the plurality of landing pads 240 and between a given one of the plurality of landing pads 240 and a given one of the plurality of bottom electrode contacts 340, a second insulating layer 180 may also be formed between the adjacent two of the plurality of landing pads 240 and between the given landing pad 240 and the given bottom electrode contact 340.

After the patterning the conductive layer 150 positioned in the first region 111, the method for fabricating a semiconductor structure also includes following steps.

As shown in FIG. 18, a capacitor 250 and a connection pad 260 connected to an upper electrode plate of the capacitor 250 are formed on each of the plurality of landing pads 240.

It is to be noted that because the memory cells of the DRAM are different from the memory cells of the MRAM, in this step, a mask needs to be employed to cover devices positioned above the second region 112, and only the capacitor 250 of the DRAM is formed. The fabrication process of the capacitor 250 is the same as the fabrication process in the existing technologies, and thus is not repeated in this embodiment.

The connection pad 260 is configured to achieve an effective connection between the upper electrode plate of the capacitor 250 and an interconnect layer formed subsequently, and after the connection pad 260 is formed, it is required to planarize a top surface of the connection pad 260 by means of chemical mechanical polishing (CMP).

In some embodiments, after the forming a capacitor 250 and a connection pad 260 connected to an upper electrode plate of the capacitor 250 on each of the plurality of landing pads 240, the method for fabricating a semiconductor structure also includes following steps.

As shown in FIG. 19, a plurality of first conductive pillars 270 spaced apart are formed on the connection pad 260, and a second conductive pillar 360 is formed on each of the magnetic tunnel junctions 350. A top surface of each of the plurality of first conductive pillars 270 is flush with a top surface of the second conductive pillar 360.

Because the plurality of first conductive pillars 270 have the structure as the second conductive pillar 360, they can be fabricated by means of the same fabrication process. In this way, fabrication processes of the semiconductor structure can be simplified, and production costs can be saved.

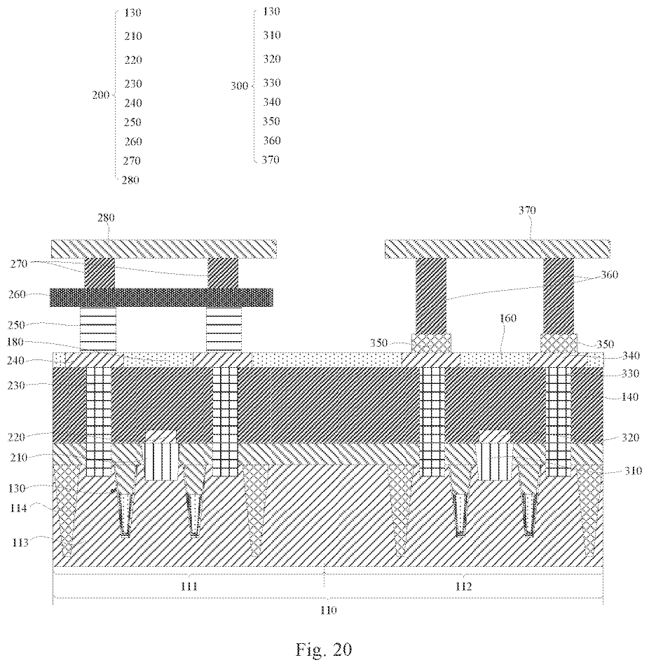

As shown in FIG. 20, after the forming a plurality of first conductive pillars 270 spaced apart on the connection pads 260 and forming a second conductive pillar 360 on each of the magnetic tunnel junctions 350, the method for fabricating a semiconductor structure also includes following steps.

An interconnect layer 280 is formed on each of the plurality of first conductive pillars 270, and a second bit line structure 370 is formed on the second conductive pillar 360, where the interconnect layer 280 and the second bit line structure 370 are positioned on the same layer.

In this embodiment, the interconnect layer 280 may be positioned on the same layer as a metal layer M1 in the peripheral circuit region, and the interconnect layer 280 is configured to transmit a signal from the peripheral circuit region to the capacitor 250. The second bit line structure 370 is electrically connected to the magnetic tunnel junction 350 by means of the second conductive pillar 360, to read data from the magnetic tunnel junction 350 or write data into the magnetic tunnel junction 350.

The embodiments of the present disclosure also provide a semiconductor structure, which is fabricated by the method for fabricating a semiconductor structure in the above-mentioned embodiments.

As shown in FIG. 20, the semiconductor structure includes a substrate 100 having an array region 110, a first memory 200, and a second memory 300.

The array region 110 includes a first region 111 and a second region 112 arranged adjacently, where the first region 111 and the second region 112 are arranged side by side, or the first region 111 is arranged around the second region 112 (as shown in FIG. 2), or the second region 112 is arranged around the first region 111.

The first memory 200 is arranged in the first region 111, and the second memory 300 is arranged in the second region 112, where the first memory 200 includes a dynamic random access memory (DRAM), and the second memory 300 includes a magnetic random access memory (MRAM).

In this embodiment, the first memory 200 and the second memory 300 are respectively formed in the first region and the second region by means of the process configured for fabricating the first memory, such that the same semiconductor structure has two different types of memories. In this way, fabrication steps of the semiconductor structure can be simplified, and performance of the semiconductor structure can also be improved.

In some embodiments, the first memory 200 also includes a bit line contact structure 210, the second memory 300 also includes a source line contact structure 310, and the bit line contact structure 210 and the source line contact structure 310 are positioned in the same layer and are fabricated by means of the same process. In this way, the fabrication steps of the semiconductor structure can be simplified, and the production cost can be saved.

In some embodiments, the first memory 200 also includes a first bit line structure 220 connected to the bit line contact structure 210, and the second memory 300 also includes a source line structure 320 connected to the source line contact structure 310, where the source line structure 320 and the first bit line structures 220 are positioned in the same layer and are fabricated by means of the same process step.

The first memory 200 also includes a capacitive contact structure 230 configured to connect the plurality of active areas 113 positioned in the first region 111 and the capacitor 250 of the first memory 200.

The second memory 300 includes a conductive plug 330 configured to connect the plurality of active areas 113 positioned in the second region 112 and the magnetic tunnel junction 350 of the second memory 300. The conductive plug 330 and the capacitive contact structure 230 are positioned in the same layer and are fabricated by means of the same process step.

The first memory 200 includes a landing pad 240, which is arranged between the capacitive contact structure 230 and the capacitor 250 and is connected to the capacitive contact structure 230 and the capacitor 250, respectively.

The second memory 300 includes a bottom electrode contact 340, which is arranged between the conductive plug 330 and the magnetic tunnel junction 350 and is respectively connected to the conductive plug 330 and the magnetic tunnel junction 350, where the landing pad 240 and the bottom electrode contact 340 are positioned on the same layer.

The first memory 200 includes an interconnect layer 280 electrically connected to the capacitor 250 by means of a first conductive pillar 270, and the second memory 300 includes a second bit line structure 370 connected to the magnetic tunnel junction 350 by means of the second conductive pillar 360. The interconnect layer 280 and the second bit line structure 370 are positioned in the same layer and are fabricated by means of the same process step.

In this embodiment, except that the capacitor 250 of the first memory 200 and the magnetic tunnel junction 350 of the second memory 300 are not fabricated in the same process step, rest of the functional devices are all fabricated in the same step. In this way, the fabrication steps of the semiconductor structure can be simplified, and the performance of the semiconductor structure can also be improved.

The embodiments or the implementations in the specification are described in a progressive manner. Each of the embodiments is focused on difference from other embodiments, and cross reference is available for identical or similar parts among different embodiments.

In the descriptions of this specification, descriptions of reference terms “one embodiment”, “some embodiments”, “an exemplary embodiment”, “an example”, “one example”, or “some examples” are intended to indicate that features, structures, materials, or characteristics described with reference to the embodiment or example are included in at least one embodiment or example of the present disclosure.

The schematic representation of the above terms throughout this specification does not necessarily refer to the same embodiment or example. Furthermore, the features, structures, materials, or characteristics set forth may be combined in any suitable manner in one or more embodiments or examples.

Finally, it should be noted that the foregoing embodiments are merely intended for describing the technical solutions of the present disclosure, but not for limiting the present disclosure. Although the present disclosure is described in detail with reference to the foregoing embodiments, persons of ordinary skill in the art should understand that they may still make modifications to the technical solutions described in the foregoing embodiments or make equivalent replacements to some or all technical features thereof, which does not make corresponding technical solutions in essence depart from the scope of the technical solutions of the embodiments of the present disclosure.

What is claimed is:

1. A method for fabricating a semiconductor structure comprising:
providing a substrate having an array region comprising a first region and a second region arranged adjacently; and
forming a first memory in the first region and forming a second memory in the second region by means of a same fabrication process, the fabrication process being a process configured for fabricating the first memory.

2. The method for fabricating a semiconductor structure according to claim 1, wherein the first memory is a dynamic random access memory, the second memory being a magnetic random access memory, and the fabrication process being a process configured for fabricating the dynamic random access memory.

3. The method for fabricating a semiconductor structure according to claim 1, wherein the fabrication method comprises:
forming a plurality of active areas spaced apart and isolation structures configured to separate the plurality of active areas in the substrate; and
forming buried-gate transistors in each of the plurality of active areas, wherein one of the buried-gate transistors positioned in the first region serves as a read/write transistor of the first memory, and other one of the buried-gate transistors positioned in the second region serves as a read/write transistor of the second memory.

4. The method for fabricating a semiconductor structure according to claim 3, wherein number of the buried-gate transistors in each of the plurality of active areas is two, and gate structures of the two buried-gate transistors share a same source or a same drain.

5. The method for fabricating a semiconductor structure according to claim 3, wherein after the forming buried-gate transistors in each of the plurality of active areas, the fabrication method further comprises:
forming a plurality of grooves spaced apart in the substrate, each of the plurality of grooves exposing part of one of the plurality of active areas; and
forming a first conductive structure in each of the plurality of grooves, wherein the first conductive structure positioned in the first region serves as a bit line contact structure of the first memory, and the first conductive structure positioned in the second region serves as a source line contact structure of the second memory.

6. The method for fabricating a semiconductor structure according to claim 5, wherein after the forming a first conductive structure in each of the plurality of grooves, the fabrication method further comprises:
forming a first bit line structure and a source line structure on the substrate, the first bit line structure being positioned in the first region and being connected to the bit line contact structure, and the source line structure being positioned in the second region and being connected to the source line contact structure.

7. The method for fabricating a semiconductor structure according to claim 5, wherein after the forming a first bit line structure and a source line structure on the substrate, the fabrication method further comprises:
forming a first dielectric layer covering the first bit line structure and the source line structure; and
forming a plurality of second conductive structures spaced apart in the first dielectric layer, wherein some of the plurality of second conductive structures positioned in the first region serve as capacitive contact structures electrically connected to some of the plurality of active areas positioned in the first region, some of the plurality of second conductive structures positioned in the second region serving as conductive plugs electrically connected to some of the plurality of active areas positioned in the second region.

8. The method for fabricating a semiconductor structure according to claim 7, wherein after the forming a plurality of second conductive structures spaced apart in the first dielectric layer, the fabrication method further comprises:
forming a conductive layer on the first dielectric layer; and
patterning the conductive layer positioned in the second region to form a plurality of bottom electrode contacts spaced apart, wherein each of the plurality of bottom electrode contacts is electrically connected to one of the conductive plugs positioned in the second region.

9. The method for fabricating a semiconductor structure according to claim 8, wherein after the forming a plurality of bottom electrode contacts spaced apart on the first dielectric layer, the fabrication method further comprises:
forming a magnetic tunnel junction on each of the plurality of bottom electrode contacts.

10. The method for fabricating a semiconductor structure according to claim 9, wherein after the forming a magnetic tunnel junction on each of the plurality of bottom electrode contacts, the fabrication method further comprises:
patterning the conductive layer positioned in the first region to form a plurality of landing pads spaced apart, the plurality of landing pads being arranged in a one-to-one correspondence with the plurality of capacitive contact structures.

11. The method for fabricating a semiconductor structure according to claim 10, wherein after the patterning the conductive layer positioned in the first region, the fabrication method further comprises:
forming a capacitor and a connection pad connected to an upper electrode plate of the capacitor on each of the plurality of landing pads.

12. The method for fabricating a semiconductor structure according to claim 11, wherein after the forming a capacitor and a connection pad connected to an upper electrode plate of the capacitor on each of the plurality of landing pads, the fabrication method further comprises:
forming a plurality of first conductive pillars spaced apart on the connection pad, and forming a second conductive pillar on each of the magnetic tunnel junctions, a top surface of the plurality of first conductive pillars being flush with a top surface of the second conductive pillar.

13. The method for fabricating a semiconductor structure according to claim 12, wherein after the forming a plurality of first conductive pillars spaced apart on the connection pad, and forming a second conductive pillar on each of the magnetic tunnel junctions, the fabrication method further comprises:
forming an interconnect layer on each of the plurality of first conductive pillars and forming a second bit line structure on the second conductive pillar, the interconnect layer and the second bit line structure being positioned on a same layer.

14. The method for fabricating a semiconductor structure according to claim 3, wherein the forming buried-gate transistors in each of the plurality of active areas comprises:
forming, in each of the plurality of active areas, a gate trench, and a source and a drain respectively positioned on two sides of the gate trench;
forming a gate structure in each of the gate trenches, wherein the gate structure comprises an oxide layer and a barrier layer stacked on an inner wall of the gate trench, and a gate arranged in a region enclosed by the barrier layer, the gate being flush with a top surface of the barrier layer and being lower than a top surface of the oxide layer; and
forming a gate protection layer, the gate protection layer covering a surface of the substrate and filling up the gate trench positioned above the gate.

15. A semiconductor structure, the semiconductor structure being fabricated by a method for fabricating a semiconductor structure, the method comprises:
providing a substrate having an array region comprising a first region and a second region arranged adjacently; and
forming a first memory in the first region and forming a second memory in the second region by means of a same fabrication process, the fabrication process being a process configured for fabricating the first memory;
wherein the semiconductor structure comprises:
a substrate having an array region, the array region comprising a first region and a second region arranged adjacently;
a first memory arranged in the first region; and
a second memory arranged in the second region.

16. The semiconductor structure according to claim 15, wherein the first memory comprises a dynamic random access memory, the second memory comprising a magnetic random access memory; and
the first memory further comprises a bit line contact structure, the second memory further comprising a source line contact structure, and the bit line contact structure and the source line contact structure being positioned in a same layer and being fabricated by means of a same process step.

17. The semiconductor structure according to claim 16, wherein the first memory further comprises a first bit line structure connected to the bit line contact structure, the second memory further comprising a source line structure connected to the source line contact structure; and
the source line structure and the first bit line structure are positioned in a same layer and are fabricated by means of a same process step.

18. The semiconductor structure according to claim 17, wherein the first memory further comprises a capacitive contact structure configured to connect an active area positioned in the first region and a capacitor of the first memory;
the second memory comprises a conductive plug configured to connect an active area positioned in the second region and a magnetic tunnel junction of the second memory; and
the conductive plug and the capacitive contact structure are positioned in a same layer and are fabricated by means of a same process step.

19. The semiconductor structure according to claim 18, wherein the first memory comprises a landing pad arranged between the capacitive contact structure and the capacitor and connected to the capacitive contact structure and the capacitor, respectively;
the second memory comprises a bottom electrode contact arranged between the conductive plug and the magnetic tunnel junction and connected to the conductive plug and the magnetic tunnel junction, respectively; and
the landing pad and the bottom electrode contact are positioned on a same layer.

20. The semiconductor structure according to claim 18, wherein the first memory comprises an interconnect layer electrically connected to the capacitor by means of a first conductive pillar; and
the second memory comprises a second bit line structure connected to the magnetic tunnel junction by means of a second conductive pillar, the interconnect layer and the second bit line structure being positioned in a same layer and being fabricated by means of a same process step.
